(19) United States
(12) Patent Application Publication
(10) Pub. No.: US 2023/0105374 A1
(43) Pub. Date: Apr. 6, 2023

(54) DISPLAY APPARATUS

(71) Applicant: Samsung Display Co., Ltd., Yongin-si (KR)

(72) Inventors: Seungyeon Jeong, Yongin-si (KR); Ohjeong Kwon, Yongin-si (KR); Hyeoji Kang, Yongin-si (KR); Wooyoung Kim, Yongin-si (KR); Taeho Kim, Yongin-si (KR); Hongyeon Lee, Yongin-si (KR)

(21) Appl. No.: 17/887,274

(22) Filed: Aug. 12, 2022

(30) Foreign Application Priority Data
Oct. 6, 2021 (KR) 10-2021-0132685

(51) Int. Cl. H01L 27/32; H01L 51/52

(52) U.S. Cl. CPC H01L 27/3218; H01L 51/5284; H01L 27/3216; H01L 27/3246; H01L 27/322; H01L 51/5271; H01L 2251/303

(57) ABSTRACT

A display apparatus that includes a substrate; a first light-emitting device, a second light-emitting device, and a third light-emitting device, which are arranged on the substrate and respectively form emission areas by emitting light of wavelengths different from one another; a low-reflection layer arranged on the first light-emitting device, the second light-emitting device, and the third light-emitting device and including an inorganic material; a light-shielding layer arranged above the low-reflection layer, corresponding to a non-emission area between the emission areas and having openings corresponding to the emissions areas; a color filter layer arranged in the openings of the light-shielding layer, corresponding to only the first light-emitting device among the first light-emitting device, the second light-emitting device, and the third light-emitting device; and a reflection control layer arranged on the light-shielding layer and the color filter layer is provided.

### CROSS-REFERENCE TO RELATED APPLICATION

This application claims priority to and the benefit of Korean Patent Application No. 10-2021-0132685, filed on Oct. 6, 2021, in the Korean Intellectual Property Office, the entire contents of which are hereby incorporated by reference.

### BACKGROUND

### 1. Field

One or more embodiments of the present disclosure relate to display apparatuses, and for example, to display apparatuses having improved (increased) visibility.

### 2. Description of the Related Art

Organic light-emitting display apparatuses have self-light-emitting properties and do not require separate light sources, unlike liquid crystal display devices, thus allowing the thickness and weight thereof to be reduced. Furthermore, organic light-emitting display apparatuses have high quality characteristics such as low power consumption, high luminance, high reaction speed, and/or the like.

However, such display apparatuses according to the related art have a problem in that visibility is reduced due to reflection of external light.

### SUMMARY

One or more embodiments of the present disclosure include display apparatuses having improved (increased) visibility in which a low reflection layer and a reflection control layer are arranged on a light-emitting device. However, such an objective is an example, and the scope of the present disclosure is not limited thereby.

Additional aspects of embodiments will be set forth in part in the disclosure which follows and, in part, will be apparent from the disclosure, or may be learned by practice of the presented embodiments of the disclosure.

According to an aspect of an embodiment of the present disclosure, a display apparatus includes a substrate, a first light-emitting device, a second light-emitting device, and a third light-emitting device arranged on the substrate and respectively forming emission areas by emitting light of wavelengths different from one another, a low reflection layer arranged on the first light-emitting device, the second light-emitting device, and the third light-emitting device and including an inorganic material, a light-shielding layer arranged above the low reflection layer corresponding to a non-emission area between the emission areas and having openings respectively corresponding to the emission areas, a color filter layer arranged in the openings of the light-shielding layer corresponding to only the first light-emitting device among the first light-emitting device, the second light-emitting device, and the third light-emitting device, and a reflection control layer arranged on the light-shielding layer and the color filter layer.

According to one or more embodiments, the first light-emitting device may emit light of a red wavelength.

According to one or more embodiments, the color filter layer may transmit light in a red wavelength range.

According to one or more embodiments, the openings of the light-shielding layer may include a first opening corresponding to the first light-emitting device, a second opening corresponding to the second light-emitting device, and a third opening corresponding to the third light-emitting device, and the color filter layer may be arranged only in the first opening.

According to one or more embodiments, the reflection control layer may be arranged to fill the second opening and the third opening.

According to one or more embodiments, the thickness of the color filter layer may be about 0.9 μm to about 3.0 μm.

According to one or more embodiments, the light transmittance of the color filter layer may be 70% or more in a red wavelength range, and 50% or less in a green wavelength range and a blue wavelength range.

According to one or more embodiments, the color filter layer may include a scattering agent.

According to one or more embodiments, the scattering agent may include at least one of TiO₂, ZnO, Al₂O₃, SiO₂, hollow silica, or polystyrene particles.

According to one or more embodiments, the scattering agent may have an average diameter of about 50 nm or more and about 500 nm or less.

According to one or more embodiments, the reflection control layer may include dye, pigment, or a combination thereof.

According to one or more embodiments, the light transmittance of the reflection control layer may be 64% to 72%.

According to one or more embodiments, the low reflection layer may include ytterbium (Yb), bismuth (Bi), cobalt (Co), molybdenum (Mo), titanium (Ti), zirconium (Zr), aluminum (Al), chromium (Cr), niobium (Nb), platinum (Pt), tungsten (W), indium (In), tin (Sn), iron (Fe), nickel (Ni), tantalum (Ta), manganese (Mn), zinc (Zn), germanium (Ge), silver (Ag), magnesium (Mg), gold (Au), copper (Cu), calcium (Ca), or a combination thereof.

According to one or more embodiments, the inorganic material included in the low-reflection layer may have a refractive index (n) of 1 or more.

According to one or more embodiments, the first wavelength range may be about 480 nm to about 500 nm, and the second wavelength range may be about 585 nm to about 605 nm.

According to one or more embodiments, the first light-emitting device may include a first pixel electrode, the second light-emitting device may include a second pixel electrode, and the third light-emitting device may include a third pixel electrode, the display apparatus may further include a pixel-defining layer that covers edges of the first pixel electrode, the second pixel electrode, and the third pixel electrode, and may have an opening portion that exposes a center portion of each of the first pixel electrode, the second pixel electrode, and the third pixel electrode, wherein the pixel-defining layer may include a light-blocking material.

According to one or more embodiments, the display apparatus may further include a capping layer arranged on the first light-emitting device, the second light-emitting device, and the third light-emitting device, and including an organic material, wherein the low reflection layer may be arranged directly on the capping layer.

According to one or more embodiments, the display apparatus may further include a thin-film encapsulation layer arranged on the low reflection layer, and a touch-sensing layer arranged on the thin-film encapsulation layer, wherein the light-shielding layer may be arranged on the touch-sensing layer.

Aspects of embodiments and features other than those described above will become apparent from the following drawings, claims, and detailed description of the disclosure.

### BRIEF DESCRIPTION OF THE DRAWINGS

The above and other aspects of embodiments and features of certain embodiments of the disclosure will be more apparent from the following description taken in conjunction with the accompanying drawings, in which:

FIG. 1 is a schematic perspective view of a display apparatus according to an embodiment;

FIG. 2 illustrates a display element provided in any one pixel of a display apparatus, and a pixel circuit connected (coupled) thereto, according to an embodiment;

FIG. 3 is a schematic cross-sectional view of a display apparatus according to one or more embodiments;

FIGS. 4A and 4B are schematic plan views showing part of a pixel array to be included in a display area;

FIG. 5 is a cross-sectional view of part of a display apparatus according to an embodiment;

FIGS. 6 to 8 are cross-sectional views showing part of a display apparatus according to an embodiment, as a modified example of FIG. 5;

FIG. 9 is a graph showing the light transmittance of a reflection control layer, according to an embodiment;

FIGS. 10 and 11 are schematic cross-sectional views of part of a display apparatus according to embodiments;

FIG. 12 is a graph showing the reflection spectrums of each of a first pixel, a second pixel, and a third pixel, according to Comparative Example 1; and

FIG. 13 is a graph showing the reflection spectrum of the first pixel, according to an embodiment.

### DETAILED DESCRIPTION

Reference will now be made in more detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of embodiments of the present disclosure. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various suitable modifications may be applied to the present embodiments, and particular embodiments will be illustrated in the drawings and described in the detailed description section. The effect and features of the present embodiments, and a method to achieve the same (substantially the same), will be clearer referring to the detailed descriptions below with the drawings. However, the present embodiments may be implemented in various suitable forms, not by being limited to the embodiments presented below.

Hereinafter, embodiments will be described in more detail with reference to the accompanying drawings, and in the description with reference to the drawings, the same or corresponding constituents are indicated by the same reference numerals and redundant descriptions thereof are not repeated here.

It will be understood that although the terms “first,” “second,” etc. may be used herein to describe various suitable components, these components should not be limited by these terms. These components are only used to distinguish one component from another.

As used herein, the singular forms are intended to include the plural forms as well, unless the context clearly indicates otherwise.

It will be further understood that the terms “comprises” and/or “comprising” as used herein specify the presence of stated features or components, but do not preclude the presence or addition of one or more other features or components.

It will be understood that when a layer, region, or component is referred to as being “formed on” another layer, region, or component, it can be directly or indirectly formed on the other layer, region, or component. For example, intervening layers, regions, or components may be present.

It will be understood that when a layer, region, or component is referred to as being “connected to” (coupled to) another layer, region, or component, it can be directly connected to the other layer, region, or component or indirectly connected to the other layer, region, or component via intervening layers, regions, or components. For example, in the disclosure, when a layer, region, or component is referred to as being electrically connected to another layer, region, or component, it can be directly electrically connected to the other layer, region, or component or indirectly electrically connected to the other layer, region, or component via intervening layers, regions, or components.

In the disclosure, as used herein, the expression such as “A and/or B” may include A, B, or A and B. Furthermore, the expression such as “at least one of A and B” may include A, B, or A and B.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed at substantially the same time (substantially concurrently) or performed in an order opposite to the described order.

Sizes of components in the drawings may be exaggerated for convenience of explanation. For example, because sizes and/or thicknesses of components in the drawings may be arbitrarily illustrated for convenience of explanation, the following embodiments are not limited thereto.

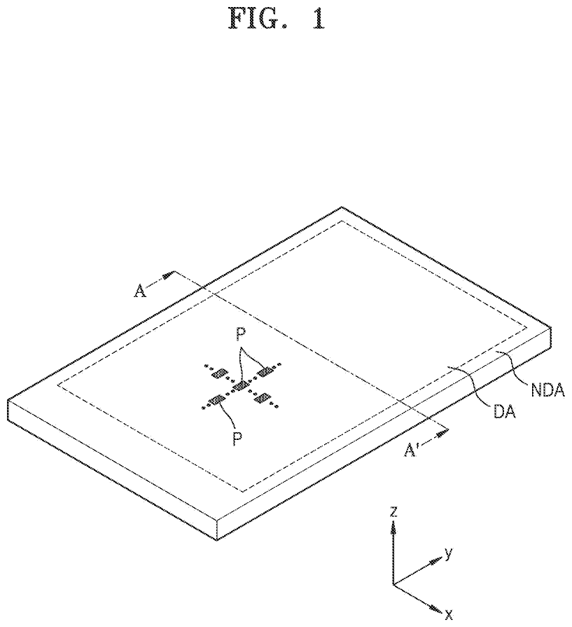

FIG. 1 is a schematic perspective view of a display apparatus 1 according to an embodiment.

Referring to FIG. 1, the display apparatus 1 according to an embodiment may include a display area DA and/or a non-display area NDA outside the display area DA. Although FIG. 1 illustrates that the display area DA has an approximately rectangular (substantially rectangular) shape, the disclosure is not limited thereto. The display area DA may have various suitable shapes such as a circle (substantially circular), an oval (substantially oval), a polygon, and/or the like.

The display area DA is a portion that displays an image, and a plurality of pixels P may be arranged in the display area DA. In the present disclosure, as used herein, the term “pixel” may mean a “sub-pixel”. Each of the pixels P may include a light-emitting device such as an organic light-emitting diode (OLED). Each of the pixels P may emit, for example, red, green, blue, or white light.

The display area DA may provide a certain image through light emitted from the pixels P. In the present disclosure, the pixels P may be defined as an emission area from which light of any one color of red, green, blue, and/or white is emitted, as described above.

The non-display area NDA is an area where the pixels P are not arranged so that no image is provided. A printed circuit board including a driving circuit portion and a power supply wiring for driving the pixels P, a terminal portion to which a driver IC is connected (coupled), and/or the like may be arranged in the non-display area NDA.

In the following description, an organic light-emitting display apparatus is described as an example of the display apparatus 1 according to an embodiment. However, the disclosure is not limited thereto. For example, the display apparatus 1 according to an embodiment may include an inorganic light-emitting display apparatus or an inorganic EL display apparatus, a quantum dot light-emitting display apparatus. For example, a light-emitting layer included in the light-emitting device provided in the display apparatus 1 may include an organic material and/or an inorganic material. Quantum dots may be located on a path of light emitted from the light-emitting layer.

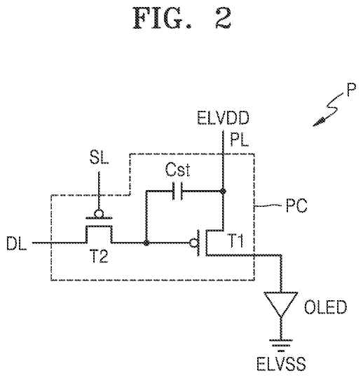

FIG. 2 illustrates a display element provided in any one pixel of the display apparatus 1, and a pixel circuit PC connected (coupled) thereto, according to an embodiment.

Referring to FIG. 2, an organic light-emitting diode OLED that is the display element is connected to a pixel circuit PC. The pixel circuit PC may include a first thin film transistor T1, a second thin film transistor T2, and a storage capacitor Cst. The organic light-emitting diode OLED may emit, for example, red, green, or blue light, or red, green, blue and/or white light.

The second thin film transistor T2, as a switching thin film transistor, is connected to a scan line SL and a data line DL, and may transmit a data voltage input through the data line DL to the first thin film transistor T1 according to a switching voltage input through the scan line SL. The storage capacitor Cst is connected to the second thin film transistor T2 and a driving voltage line PL, and may store a voltage corresponding to a difference between the voltage transmitted from the second thin film transistor T2 and a first power voltage ELVDD supplied through the driving voltage line PL.

The first thin film transistor T1, as a driving thin film transistor, is connected the driving voltage line PL and the storage capacitor Cst, and may control, in response to a voltage value stored in the storage capacitor Cst, a driving current flowing from the driving voltage line PL to the organic light-emitting diode OLED. The organic light-emitting diode OLED may emit light having a certain luminance by the driving current. A second power voltage ELVSS may be supplied to a counter electrode, for example, a cathode, of the organic light-emitting diode OLED.

Although FIG. 2 describes that the pixel circuit PC includes two thin film transistors and one storage capacitor, in another embodiment, the number of thin film transistors or storage capacitors may be changed variously (suitably) depending on the design of the pixel circuit PC.

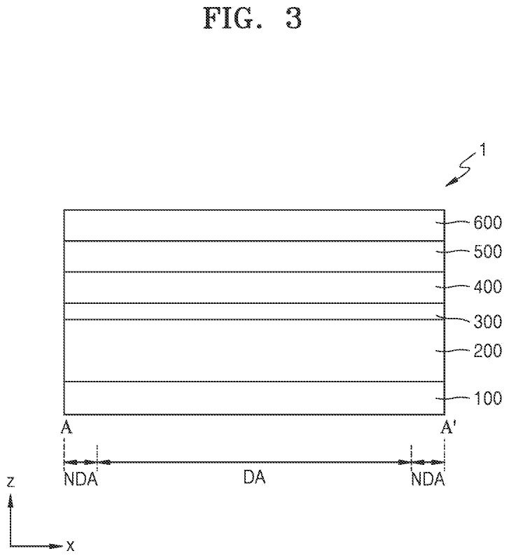

FIG. 3 is a cross-sectional view taken along line A-A′ of FIG. 1, schematically showing the display apparatus 1 according to one or more embodiments.

Referring to FIG. 3, the display apparatus 1 according to an embodiment may include a substrate 100, a display layer 200, a low reflection layer 300, a thin-film encapsulation layer 400, a touch-sensing layer 500, and an antireflective layer 600.

The substrate 100 may include glass and/or polymer resin. For example, polymer resin may include polyethersulfone, polyacrylate, polyetherimide, polyethylene naphthalate, polyethylene terephthalate, polyphenylene sulfide, polyarylate, polyimide, polycarbonate, cellulose acetate propionate, and/or the like. The substrate 100 including polymer resin may have flexible, rollable, and/or bendable characteristics. The substrate 100 may have a multilayer structure including a layer including polymer resin and an inorganic layer.

The display layer 200 may include an organic light-emitting diode that is a light-emitting device, a thin film transistor electrically connected (coupled) to the organic light-emitting diode, and insulating layers provided therebetween.

The low reflection layer 300 may be arranged on the display layer 200, and the thin-film encapsulation layer 400 may be arranged on the low reflection layer 300. For example, the display layer 200 and/or the low reflection layer 300 may be hermetically sealed by the thin-film encapsulation layer 400. The thin-film encapsulation layer 400 may include at least one inorganic film layer and at least one organic film layer.

In another embodiment, an encapsulation substrate formed of glass may be provided instead of the thin-film encapsulation layer 400. The encapsulation substrate may be arranged on the display layer 200, and the display layer 200 may be provided between the substrate 100 and the encapsulation substrate. A gap may be present between the encapsulation substrate and the display layer 200, and the gap may be filled with a filler.

The touch-sensing layer 500 may be arranged on the thin-film encapsulation layer 400. The touch-sensing layer 500 may sense an external input, for example, a touch of an object such as a finger or a stylus pen, and thus the display apparatus 1 may acquire coordinates information corresponding to a touch position. The touch-sensing layer 500 may include a touch electrode and trace lines connected (coupled) to the touch electrode. The touch-sensing layer 500 may sense an external input by a mutual capacitance method or a self-capacitance method.

The touch-sensing layer 500 may be arranged on the thin-film encapsulation layer 400. In an embodiment, the touch-sensing layer 500 may be formed directly on the thin-film encapsulation layer 400. In some embodiments, the touch-sensing layer 500 may be separately formed and then may adhere on the thin-film encapsulation layer 400 via an adhesive layer such as an optically clear adhesive (OCA).

The antireflective layer 600 may be arranged on the touch-sensing layer 500. The antireflective layer 600 may reduce reflectivity of light (external light) incident on the display apparatus 1.

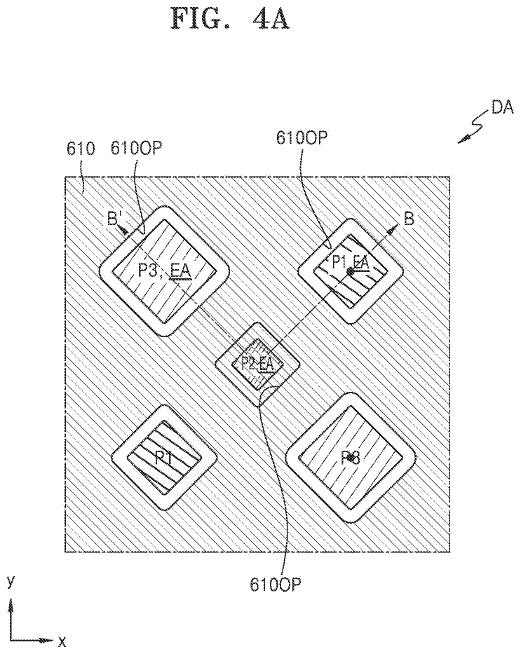

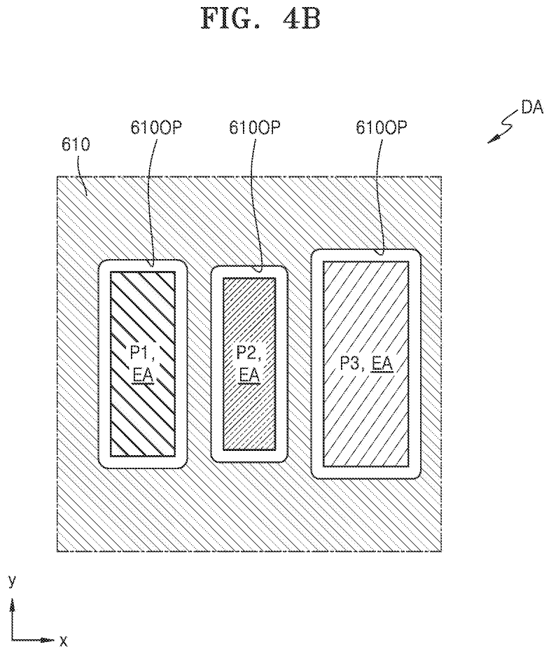

FIGS. 4A and 4B are schematic plan views showing part of a pixel array to be included in the display area DA.

Referring to FIG. 4A, the display apparatus 1 may include the pixels P, and the pixels P may include a first pixel P1, a second pixel P2, and a third pixel P3, which emits light of different colors. For example, the first pixel P1 may emit red light, the second pixel P2 may emit green light, and the third pixel P3 may emit blue light. However, the disclosure is not limited thereto. For example, various suitable modifications of the first pixel P1 emitting blue light, the second pixel P2 emitting green light, the third pixel P3 emitting red light, and/or the like may be possible.

The first pixel P1, the second pixel P2, and the third pixel P3 may each have a rectangular (substantially rectangular) shape among the polygonal shapes. In the present disclosure, a polygon or a rectangle may include a shape in which a vertex is rounded. In another embodiment, the first pixel P1, the second pixel P2, and the third pixel P3 may have a circular (substantially circular) or oval (substantially oval) shape.

The sizes of the first pixel P1, the second pixel P2, and the third pixel P3 may be different from one another. For example, the area of the second pixel P2 may be less than the areas of the first pixel P1 and the third pixel P3, and the area of the first pixel P1 may be greater than the area of the third pixel P3. In another embodiment, various suitable modifications are possible, for example, the sizes of the first pixel P1, the second pixel P2, and the third pixel P3 may be substantially the same.

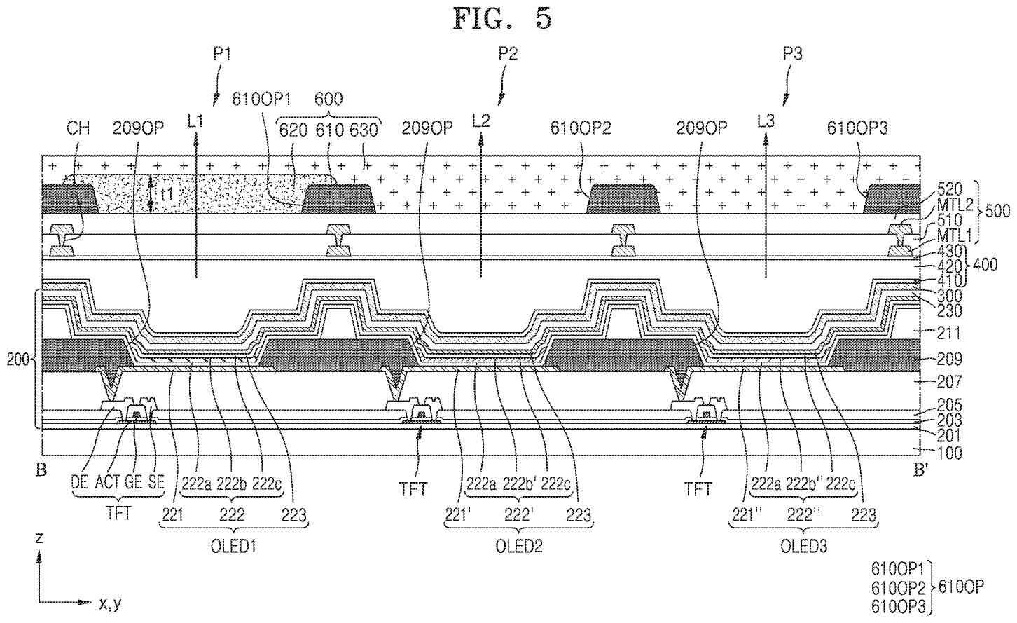

In the present disclosure, the sizes of the first pixel P1, the second pixel P2, and the third pixel P3 may refer to the size of an emission area EA of the display element forming each pixel, and the emission area EA may be defined by an opening portion 209OP of a pixel-defining layer 209 (see FIG. 5).

A light-shielding layer 610 arranged above the display layer 200 has an opening 610OP corresponding to each pixel. The opening 610OP is an area where the light-shielding layer 610 is partially removed, and thus, light emitted from the display element may be transmitted to the outside through the opening 610OP. The body of the light-shielding layer 610 may include a material capable of absorbing external light, and thus, visibility of the display apparatus 1 may be improved (increased).

When viewed from a plan view, the opening 610OP of the light-shielding layer 610 may be arranged to surround each of the first, second, and third pixels P1, P2, and P3. In an embodiment, the opening 610OP of the light-shielding layer 610 may have a rectangular (substantially rectangular) shape having a rounded corner. The area of each opening 610OP of the light-shielding layer 610 corresponding to each of the first, second, and third pixels P1, P2, and P3 may be greater than the area of each of the first, second, and third pixels P1, P2, and P3. However, the disclosure is not limited thereto. The area of each of the opening 610OP of the light-shielding layer 610 may be substantially the same as the area of each of the first, second, and third pixels P1, P2, and P3.

As illustrated in FIG. 4A, the first pixel P1, the second pixel P2, and the third pixel P3 may be arranged in a pixel array of the PENTILE® arrangement structure (for example, an RGBG matrix, an RGBG structure, or RGBG matrix structure) but, the present disclosure is not limited thereto. PENTILE® is a duly registered trademark of Samsung Display Co., Ltd. For example, as illustrated in FIG. 4B, the first pixel P1, the second pixel P2, and the third pixel P3 may be arranged in a stripe structure. Furthermore, in another embodiment, the first pixel P1, the second pixel P2, and the third pixel P3 may be arranged in various suitable pixel array structures such as a mosaic structure, a delta structure, and/or the like.

Hereinafter, the display apparatus 1 according to an embodiment is described below in more detail according to a stack order illustrated in FIG. 5.

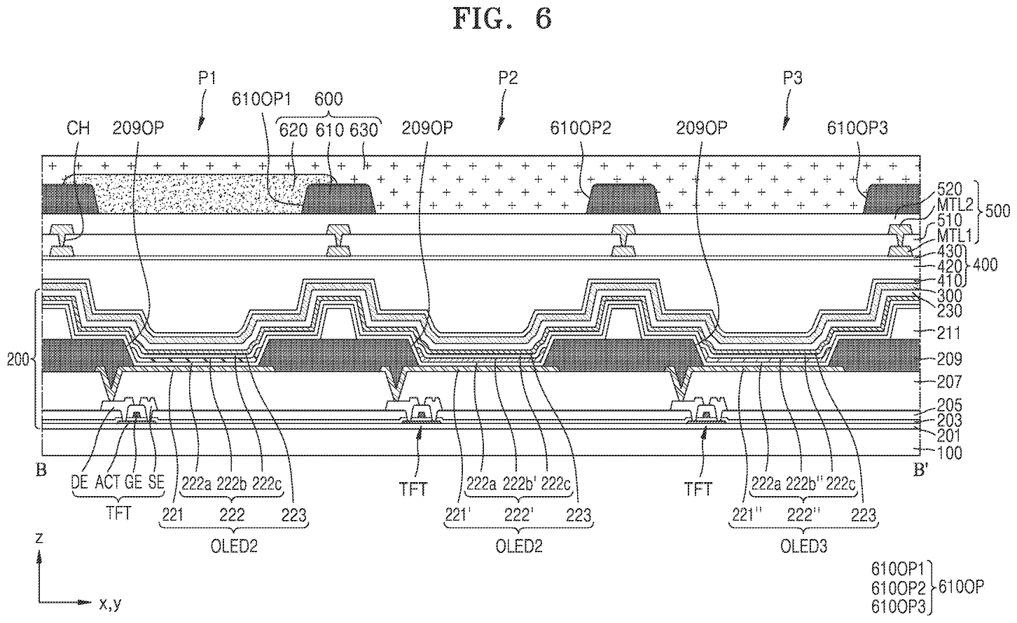

FIG. 5 is a cross-sectional view of part of a display apparatus according to an embodiment. FIGS. 6 to 8 are cross-sectional views showing part of a display apparatus according to an embodiment, as a modified example of FIG. 5.

Referring to FIG. 5, the display apparatus 1 according to an embodiment may include the substrate 100, the display layer 200, the low reflection layer 300, the thin-film encapsulation layer 400, the touch-sensing layer 500, and the antireflective layer 600.

The display layer 200 may include first to third organic light-emitting diodes OLED1, OLED2, and OLED3 and a thin film transistor TFT, and include a buffer layer 201, a gate insulating layer 203, an interlayer insulating layer 205, a planarization layer 207, a pixel-defining layer 209, and a spacer 211, which are insulating layers. In an embodiment, the display layer 200 may further include a capping layer 230 arranged on the first to third organic light-emitting diodes OLED1, OLED2, and OLED3.

The buffer layer 201 may be positioned on the substrate 100 to reduce or block (substantially block) the infiltration of foreign materials, moisture, and/or external air from the bottom of the substrate 100, and may provide a planarized surface on the substrate 100. The buffer layer 201 may include an inorganic material such as oxide and/or nitride, an organic material, and/or an organic/inorganic complex, and may have a single layer or multilayer structure of an inorganic material and/or an organic material. A barrier layer for blocking or reducing infiltration of external air may be provided between the substrate 100 and the buffer layer 201. The buffer layer 201 may include silicon oxide (SiO₂) and/or silicon nitride (SiN_{X}).

The thin film transistor TFT may be arranged on the buffer layer 201. The thin film transistor TFT may include a semiconductor layer ACT, a gate electrode GE, a source electrode SE, and a drain electrode DE. The thin film transistor TFT may be connected (coupled) to the organic light-emitting diode OLED to drive the same.

The semiconductor layer ACT may be arranged on the buffer layer 201 and may include polysilicon. In some embodiments, the semiconductor layer ACT may include amorphous silicon. In some embodiments, the semiconductor layer ACT may include an oxide of at least one material selected from the group consisting of indium (In), gallium (Ga), tin (Sn), zirconium (Zr), vanadium (V), hafnium (Hf), cadmium (Cd), germanium (Ge), chromium (Cr), titanium (Ti), and zinc (Zn). The semiconductor layer ACT may include a channel region, and a source region and a drain region that are doped with impurities.

The gate electrode GE, the source electrode SE, and the drain electrode DE may be formed of various suitable conductive materials. The gate electrode GE may include at least one material selected from the group consisting of molybdenum, aluminum, copper, and titanium. For example, the gate electrode GE may be a single layer of molybdenum, or have a three-layer structure of a molybdenum layer, an aluminum layer, and a molybdenum layer. The source electrode SE and the drain electrode DE may each include at least one material selected from the group consisting of copper, titanium, and aluminum. For example, the source electrode SE and the drain electrode DE may each have a three-layer structure of a titanium layer, an aluminum layer, and a titanium layer.

In order to secure insulation between the semiconductor layer ACT and the gate electrode GE, the gate insulating layer 203 including an inorganic material such as silicon oxide, silicon nitride, silicon oxynitride, and/or the like may be provided between the semiconductor layer ACT and the gate electrode GE. In addition, the interlayer insulating layer 205 including an inorganic material such as silicon oxide, silicon nitride, silicon oxynitride, and/or the like may be arranged above the gate electrode GE, and the source electrode SE and the drain electrode DE may be arranged above the interlayer insulating layer 205. As such, an insulating film including an inorganic material may be formed through chemical vapor deposition (CVD) or atomic layer deposition (ALD) or other suitable method apparent to one of ordinary skill in the art upon reviewing the present disclosure. The same (or substantially the same) applies to the embodiments described below.

The planarization layer 207 may be arranged on the thin film transistor TFT. To provide a flat upper surface, after the planarization layer 207 is formed, chemical mechanical polishing may be performed on an upper surface of the planarization layer 207. The planarization layer 207 may include a general purpose polymer such as photosensitive polyimide, polyimide, polystyrene (PS), polycarbonate (PC), benzocyclobutene (BCB), hexamethyldisiloxane (HMDSO), polymethylmethacrylate (PMMA), polystyrene (PS), polymer derivatives having a phenolic group, acrylic polymer, imide-based polymer, arylether-based polymer, amide-based polymer, fluorine-based polymer, p-xylene-based polymer, vinyl alcohol-based polymer, and/or the like. Although FIG. 6 illustrates that the planarization layer 207 is a single layer, the planarization layer 207 may be a multilayer.

The first to third organic light-emitting diodes OLED1, OLED2, and OLED3 may be arranged on planarization layer 207. The first organic light-emitting diode OLED1 may include a first pixel electrode 221, a first intermediate layer 222 including a first common layer 222a, a first light-emitting layer 222b, and a second common layer 222c, and a counter electrode 223. The second organic light-emitting diode OLED2 may include a second pixel electrode 221′, a second intermediate layer 222′ including the first common layer 222a, a second light-emitting layer 222b′, and the second common layer 222c, and the counter electrode 223. The third organic light-emitting diode OLED3 may include a third pixel electrode 221″, a third intermediate layer 222″ including the first common layer 222a, a third light-emitting layer 222b″, and the second common layer 222c, and the counter electrode 223.

In the following description, the description is based on the first organic light-emitting diode OLED1 included in the first pixel P1, and the stack structure of each of the second organic light-emitting diode OLED2 and the third organic light-emitting diode OLED3 is substantially the same as the first organic light-emitting diode OLED1, and thus, a redundant description thereof is not repeated here.

The first organic light-emitting diode OLED1 may include the first pixel electrode 221 (hereinafter, referred to as the pixel electrode 221), the first intermediate layer 222 (hereinafter, referred to as the intermediate layer 222), and the counter electrode 223.

The pixel electrode 221 may be arranged on the planarization layer 207. The pixel electrode 221 may be arranged for each pixel. The pixel electrodes 221 respectively corresponding to the neighboring pixels may be arranged spaced apart from each other.

The pixel electrode 221 may be a reflection electrode. In this case, the pixel electrode 221 may include a reflective film including silver (Ag), magnesium (Mg), aluminum (Al), platinum (Pt), palladium (Pd), gold (Au), nickel (Ni), neodymium (Nd), iridium (Ir), chromium (Cr), and/or compounds thereof, and a transparent or translucent conductive layer formed on reflective film. A transparent or translucent electrode layer may include at least one material selected from the group consisting of indium tin oxide (ITO), indium zinc oxide (IZO), zinc oxide (ZnO), indium oxide (In₂O₃), indium gallium oxide (IGO), and aluminum zinc oxide (AZO). For example, the pixel electrode 221 may have a stack structure of ITO/Ag/ITO.

The pixel-defining layer 209 may be arranged on the pixel electrode 221. The pixel-defining layer 209 may have the opening portion 209OP that exposes the center portion of each pixel electrode 221. The pixel-defining layer 209 covers the edge of the pixel electrode 221, and increases a distance between the edge of the pixel electrode 221 and the counter electrode 223 so that occurrence of an arc at the edge of the pixel electrode 221 may be prevented or reduced.

The pixel-defining layer 209 may include an organic insulating material. In some embodiments, the pixel-defining layer 209 may include an inorganic insulating material such as silicon nitride, silicon oxynitride, and/or silicon oxide. In some embodiments, the pixel-defining layer 209 may include an organic insulating material and inorganic insulating material. In an embodiment, the pixel-defining layer 209 may include a light-blocking material and may be provided in black. The light-blocking material may include carbon black, carbon nanotube, resin and/or paste including black dye, metal particles, for example, nickel, aluminum, molybdenum, and/or an alloy thereof, metal oxide particles, for example, chromium oxide, and/or metal nitride particles, for example, chromium nitride, and/or the like. When the pixel-defining layer 209 includes the light-blocking material, the reflection of external light due to metal structures arranged below the pixel-defining layer 209 may be reduced. However, the disclosure is not limited thereto. In another embodiment, as illustrated in FIG. 6, the pixel-defining layer 209 may include a light transmitting organic insulating material, not the light-blocking material.

The spacer 211 may be arranged on the pixel-defining layer 209. The spacer 211 may include an organic insulating material such as a polyimide. In some embodiments, the spacer 211 may include an inorganic insulating material such as silicon nitride (SiN_{X}) and/or silicon oxide (SiO₂), or an organic insulating material and an inorganic insulating material.

In an embodiment, the spacer 211 may include the same (substantially the same) material as the pixel-defining layer 209. In this case, the pixel-defining layer 209 and the spacer 211 may be formed together in a mask process using a half-tone mask, or other suitable process apparent to one of ordinary skill in the art upon reviewing the present disclosure. In an embodiment, the spacer 211 and the pixel-defining layer 209 may include different materials.

The intermediate layer 222 may be arranged on the pixel electrode 221 and the pixel-defining layer 209. The intermediate layer 222 may include the first common layer 222a, the light-emitting layer 222b and the second common layer 222c.

The light-emitting layer 222b may be arranged in the opening portion 209OP of the pixel-defining layer 209. The light-emitting layer 222b may include an organic material including a fluorescent or phosphorescent material capable of emitting blue, green, or red light. The above-described organic material may be a low molecular weight organic material or a polymer organic material. In some embodiments, the light-emitting layer 222b may include an inorganic material including quantum dots and/or the like. In more detail, the quantum dots may be semiconductor compound crystals, and the semiconductor compound crystals may include a material capable of emitting light of various suitable light-emitting wavelengths depending on the sizes of the crystals. The quantum dots may include, for example, group III-VI semiconductor compounds, group II-VI semiconductor compounds, group III-V semiconductor compounds, group III-VI semiconductor compounds, group semiconductor compounds, group IV-VI semiconductor compounds, group IV elements or compounds, and/or combinations thereof.

The first common layer 222a and the second common layer 222c may be arranged below and above the light-emitting layer 222b. The first common layer 222a may include, for example, a hole transport layer (HTL), or a HTL and a hole injection layer (HIL). The second common layer 222c may include, for example, an electron transport layer (ETL), or an ETL and an electron injection layer (EIL). In an embodiment, the second common layer 222c may not be provided.

Whereas the light-emitting layer 222b is arranged for each pixel to correspond to the opening portion 209OP of the pixel-defining layer 209, the first common layer 222a and the second common layer 222c may each be integrally formed to entirely cover the substrate 100. For example, the first common layer 222a and the second common layer 222c may each be integrally formed to entirely cover (substantially entirely cover) the display area DA of the substrate 100.

The counter electrode 223 may be a cathode that is an electron injection electrode. The counter electrode 223 may include a conductive material having a low work function. For example, the counter electrode 223 may include a (semi-) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), ytterbium (Yb), and/or an alloy thereof. In an example, the counter electrode 223 may include AgMg, AgYb, and/or the like. In some embodiments, the counter electrode 223 may further include a layer such as ITO, IZO, ZnO, and/or In₂O₃ on the (semi-)transparent layer including the material described above. The layers from the pixel electrode 221 to the counter electrode 223 may form the organic light-emitting diode OLED.

In an embodiment, the display apparatus 1 may further include the capping layer 230 arranged on the organic light-emitting diode OLED. The capping layer 230 may improve (increase) the light-emitting efficiency of the organic light-emitting diode OLED by the principle of constructive interference. The capping layer 230 may include, for example, a material having a refractive index of 1.6 or more with respect to light having a 589 nm wavelength.

The capping layer 230 may include an organic capping layer including an organic material, an inorganic capping layer including an inorganic material, or a composite capping layer including an organic material and an inorganic material. For example, the capping layer 230 may include carbocyclic compounds, heterocyclic compounds, amine group-containing compounds, porphine derivatives, phthalocyanine derivatives, naphthalocyanine derivatives, alkali metal complexes, alkali earth metal complexes, or any combination thereof. The carbocyclic compound, the heterocyclic compound, and the amine group-containing compound may be optionally substituted with a substituent including O, N, S, Se, Si, F, Cl, Br, I, or any combination thereof.

The low reflection layer 300 may be arranged on the capping layer 230. As the capping layer 230 may be arranged on the organic light-emitting diode OLED, it may be said that the low reflection layer 300 is arranged on the organic light-emitting diode OLED. The low reflection layer 300 may include an inorganic material having low reflectivity, and may include metal and/or metal oxide according to an embodiment. When the low reflection layer 300 includes metal, the low reflection layer 300 may include, for example, ytterbium (Yb), bismuth (Bi), cobalt (Co), molybdenum (Mo), titanium (Ti), zirconium (Zr), aluminum (Al), chromium (Cr), niobium (Nb), platinum (Pt), tungsten (W), indium (In), tin (Sn), iron (Fe), nickel (Ni), tantalum (Ta), manganese (Mn), zinc (Zn), germanium (Ge), silver (Ag), magnesium (Mg), gold (Au), copper (Cu), calcium (Ca), or a combination thereof. Furthermore, when the low reflection layer 300 includes metal oxide, the low reflection layer 300 may include, for example, SiO₂, TiO₂, ZrO₂, Ta₂O₅, HfO₂, Al₂O₃, ZnO, Y₂O₃, BeO, MgO, PbO₂, WO₃, SiNx, LiF, CaF₂, MgF₂, CdS, or a combination thereof.

In an embodiment, an absorption coefficient k of the inorganic material included in the low reflection layer 300 may be 4.0 or less and 0.5 or more (0.5≤k≤4.0). Furthermore, the inorganic material included in the low reflection layer 300 may have a refractive index n of 1 or more (n≥1.0).

The low reflection layer 300 induces destructive interference between the light input into the display apparatus 1 and the light reflected from the metal layers arranged below the low reflection layer 300, and thus, the reflectivity of external light may be reduced. Accordingly, as the reflectivity of external light of the display apparatus 1 is reduced through the low reflection layer 300, the display quality and visibility of the display apparatus 1 may be improved (quality and/or visibility increases).

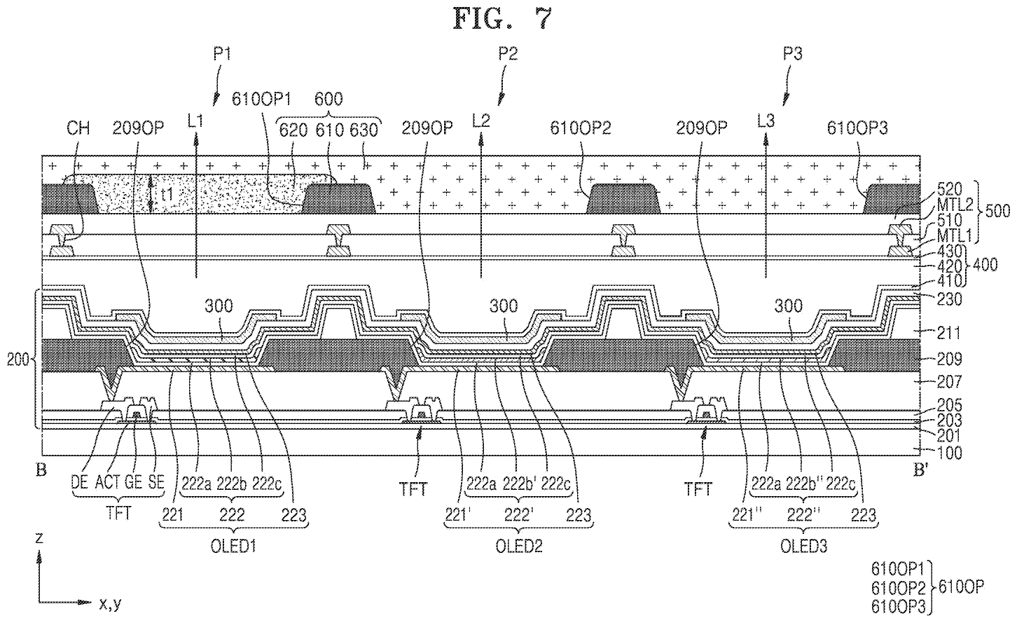

Although FIG. 5 illustrates a structure in which the low reflection layer 300 is arranged on the entire surface of the substrate 100 such as the counter electrode 223 and the capping layer 230, the disclosure is not limited thereto. As illustrated in FIG. 7, the low reflection layer 300 may be provided by being patterned for each pixel. In this case, the low reflection layer 300 may be patterned to correspond to the emission area EA of each pixel, and the area of the low reflection layer 300 may be the same as (substantially the same as) or greater than the area of the emission area EA.

The thin-film encapsulation layer 400 may be arranged on the low reflection layer 300. The thin-film encapsulation layer 400 may include at least one inorganic film layer and at least one organic film layer. For example, the thin-film encapsulation layer 400 may include a first inorganic encapsulation layer 410, an organic encapsulation layer 420, and a second inorganic encapsulation layer 430, which are sequentially stacked.

The first inorganic encapsulation layer 410 and the second inorganic encapsulation layer 430 may include an inorganic insulating material such as silicon oxide (SiO₂), silicon nitride (SiN_{X}), oxynitride silicon (SiON), aluminum oxide (Al₂O₃), titanium oxide (TiO₂), tantalum oxide (Ta₂O₅), hafnium oxide (HfO₂), zinc oxide (ZnO), and/or the like. The first inorganic encapsulation layer 410 and the second inorganic encapsulation layer 430 may each have a single layer or multilayer structure including the inorganic insulating material described above.

The organic encapsulation layer 420 may reduce internal stress of the first inorganic encapsulation layer 410 and/or the second inorganic encapsulation layer 430. The organic encapsulation layer 420 may include a polymer-based material. The polymer-based material may include polyethylene terephthalate, polyethylene naphthalate, polycarbonate, polyimide, polyethylene sulfonate, polyoxymethylene, polyarylate, hexamethyldisiloxane, acrylic resin, for example, polymethylmethacrylate, polyacryl acid, and/or the like, or any combination thereof.

The organic encapsulation layer 420 may be formed by coating a material having flowability and including monomers and then causing a reaction so that the monomers are combined to form a polymer using heat or light such as ultraviolet or other energy source which should be apparent to one of ordinary skill in the art upon reviewing the present disclosure. In some embodiments, the organic encapsulation layer 420 may be formed by coating a polymer material.

Even when cracks occur in the thin-film encapsulation layer 400, the thin-film encapsulation layer 400 may prevent or reduce, through the above-described multilayer structure, connection of the cracks to each other between the first inorganic encapsulation layer 410 and the organic encapsulation layer 420 or between the organic encapsulation layer 420 and the second inorganic encapsulation layer 430. Accordingly, the formation of a path through which external moisture, oxygen, and/or the like infiltrates into the display area DA may be prevented or reduced.

In an embodiment, when the thin-film encapsulation layer 400 is arranged on the organic light-emitting diode OLED, the substrate 100 may include polymer resin. However, the disclosure is not limited thereto.

The touch-sensing layer 500 may be arranged on the thin-film encapsulation layer 400. The touch-sensing layer 500 may include a first conductive layer MTL1, a first touch insulating layer 510, a second conductive layer MTL2, and a second touch insulating layer 520. The first conductive layer MTL1 may be arranged directly on the thin-film encapsulation layer 400. In this case, the first conductive layer MTL1 may be arranged directly on the second inorganic encapsulation layer 430 of the thin-film encapsulation layer 400. However, the disclosure is not limited thereto.

Furthermore, the touch-sensing layer 500 may include an insulating film provided between the first conductive layer MTL1 and the thin-film encapsulation layer 400. The insulating film may be arranged on the second inorganic encapsulation layer 430 of the thin-film encapsulation layer 400 to planarize (substantially planarize) a surface on which the first conductive layer MTL1 and/or the like is arranged. In this case, the first conductive layer MTL1 may be arranged directly on the insulating film. The insulating film may include an inorganic insulating material such as silicon oxide (SiO₂), silicon nitride (SiN_{X}), silicon oxynitride (SiON), and/or the like. In some embodiments, the insulating film may include an organic insulating material.

In an embodiment, the first touch insulating layer 510 may be arranged on the first conductive layer MTL1. The first touch insulating layer 510 may include an inorganic material or an organic material. When the first touch insulating layer 510 includes an inorganic material, the first touch insulating layer 510 may include at least one material selected from the group consisting of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. When the first touch insulating layer 510 includes an organic material, the first touch insulating layer 510 may include at least one material selected from the group consisting of an acrylic resin, a methacrylic resin, a polyisoprene, a vinyl-based resin, an epoxy-based resin, a urethane-based resin, a cellulose-based resin, and a perylene-based resin.

In an embodiment, the second conductive layer MTL2 may be arranged on the first touch insulating layer 510. The second conductive layer MTL2 may serve as a sensor for sending a user's touch input. The first conductive layer MTL1 may serve as a connection part for connecting the patterned second conductive layer MTL2 in one direction. In an embodiment, the first conductive layer MTL1 and the second conductive layer MTL2 may both serve as a sensor. In this state, the first conductive layer MTL1 and the second conductive layer MTL2 may be electrically connected (coupled) to each other via a contact hole CH. As such, as both of the first conductive layer MTL1 and the second conductive layer MTL2 serve as a sensor, the resistance of a touch electrode decreases so that the user's touch input may be quickly sensed (may be sensed more quickly).

In an embodiment, the first conductive layer MTL1 and the second conductive layer MTL2 may have, for example, a mesh structure, to transmit the light emitted from the organic light-emitting diode OLED. In this state, the first conductive layer MTL1 and the second conductive layer MTL2 may be arranged so as to not to overlap (substantially not to overlap) the emission area EA of the organic light-emitting diode OLED.

The first conductive layer MTL1 and the second conductive layer MTL2 may include a metal layer or a transparent conductive layer. The metal layer may include molybdenum (Mo), silver (Ag), titanium (Ti), copper (Cu), aluminum (Al), and/or an alloy thereof. The transparent conductive layer may include a transparent conductive oxide such as ITO, IZO, ZnO, indium tin zinc oxide (ITZO), and/or the like. In addition, the transparent conductive layer may include a conductive polymer such as PEDOT, a metal nano wire, a carbon nanotube, graphene, and/or the like.

In an embodiment, the second touch insulating layer 520 may be arranged on the second conductive layer MTL2. The second touch insulating layer 520 may include an inorganic material or an organic material. When the second touch insulating layer 520 includes an inorganic material, the second touch insulating layer 520 may include at least one material selected from the group consisting of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. When the second touch insulating layer 520 includes an organic material, the second touch insulating layer 520 may include at least one material selected from the group consisting of an acrylic resin, a methacrylic resin, a polyisoprene, a vinyl-based resin, an epoxy-based resin, a urethane-based resin, a cellulose-based resin, and a perylene-based resin.

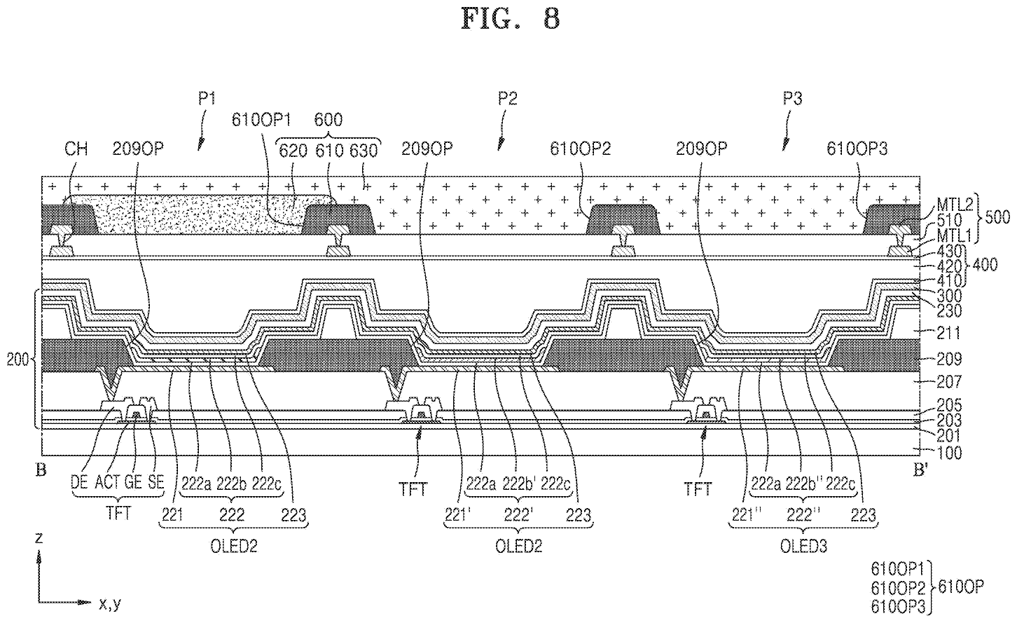

In another embodiment, as illustrated in FIG. 8, the touch-sensing layer 500 may include the first conductive layer MTL1, the first touch insulating layer 510, and the second conductive layer MTL2, and may not include the second touch insulating layer 520. In this case, the light-shielding layer 610 may have a structure of covering the second conductive layer MTL2. Part of the first touch insulating layer 510 may be exposed through the opening 610OP of the light-shielding layer 610.

The antireflective layer 600 may be arranged on the touch-sensing layer 500. The antireflective layer 600 may include the light-shielding layer 610, a color filter layer 620, and a reflection control layer 630.

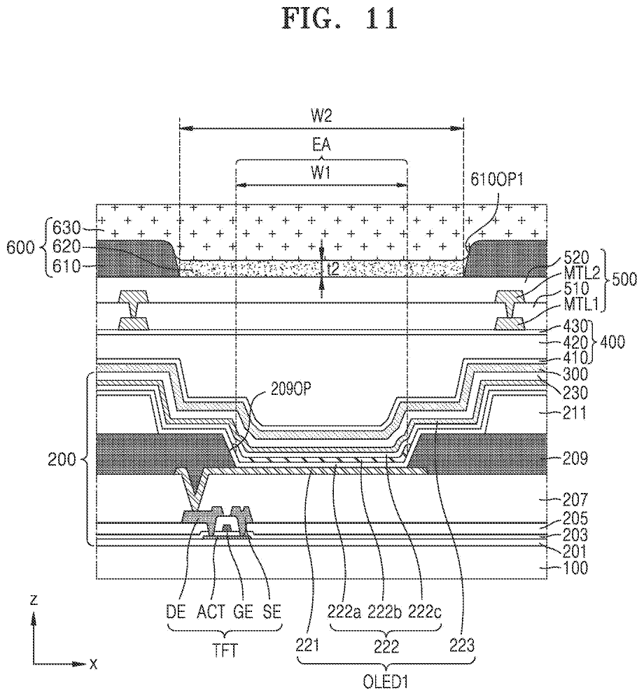

The light-shielding layer 610 may include the opening 610OP that overlaps the emission area EA. The opening 610OP may include first to third openings 610OP1, 610OP2, and 610OP3 respectively corresponding to the first to third organic light-emitting diodes OLED1, OLED2, and OLED3. The emission area EA may be defined by the opening portion 209OP of the pixel-defining layer 209, and in an embodiment, the opening 610OP of the light-shielding layer 610 may overlap the opening portion 209OP of the pixel-defining layer 209, and a second width W2 of FIG. 11 of the opening 610OP of the light-shielding layer 610 may be greater than a first width W1 of FIG. 11 of the opening portion 209OP of the pixel-defining layer 209.

A body part of the light-shielding layer 610 having the opening 610OP may overlap a body part of the pixel-defining layer 209. For example, the body part of the light-shielding layer 610 may overlap only the body part of the pixel-defining layer 209. The body part of the light-shielding layer 610 is a part distinguished from the opening 610OP of the light-shielding layer 610, and may have a volume (thickness) different than the volume (thickness) of the light-shielding layer 610. Likewise, the body part of the pixel-defining layer 209 is a part distinguished from the opening portion 209OP of the pixel-defining layer 209, and may have a volume (thickness) different than the volume (thickness) of the pixel-defining layer 209.

The color filter layer 620 may be arranged on the touch-sensing layer 500. In an embodiment, the color filter layer 620 may be arranged only on the first organic light-emitting diode OLED1. As the first organic light-emitting diode OLED1 emits light of a red wavelength range, the color filter layer 620 may be arranged to correspond to the first pixel P1 that emits light of a red wavelength range. The color filter layer 620 may be arranged to fill the inside of the first opening 610OP1 of the light-shielding layer 610 that is provided to correspond to the emission area EA of the first organic light-emitting diode OLED1.

The color filter layer 620 may transmit light of a specific wavelength range. In more detail, the color filter layer 620 may transmit only light of a wavelength range emitted from the first organic light-emitting diode OLED1. For example, the color filter layer 620 may include a red component, and the red component may include, for example, red pigment, red dye, and/or the like. In an embodiment, the color filter layer 620 may transmit red light emitted from the first organic light-emitting diode OLED1, and may increase purity of red light by absorbing a wavelength other than the red light wavelength. Furthermore, the band width of a light-emitting wavelength of the red light emitted from the first organic light-emitting diode OLED1 may decrease while the red light passes through the color filter layer 620. For example, red light of high color purity may be implemented through the color filter layer 620.

The color filter layer 620 is arranged to correspond to the first organic light-emitting diode OLED1 only, and thus, the color filter layer 620 may not be arranged on the second organic light-emitting diode OLED2 and the third organic light-emitting diode OLED3. Accordingly, a reflection control layer 630 that is described below may be embedded in a second opening 610OP2 and a third opening 610OP3 of the light-shielding layer 610 above the second organic light-emitting diode OLED2 and the third organic light-emitting diode OLED3. The reflection control layer 630 may be in direct contact with the second touch insulating layer 520 (or the first touch insulating layer 510 in the embodiment of FIG. 8) exposed through the second opening 610OP2 and the third opening 610OP3 of the light-shielding layer 610.

In an embodiment, a first thickness t1 of the color filter layer 620 may be about 0.9 μm to 3.0 μm. In more detail, the first thickness t1 of the color filter layer 620 may be about 2.7 μm to 3.0 μm. In this case, the first thickness t1 of the color filter layer 620 may be greater than the thickness of the body part of the light-shielding layer 610. The thickness of the color filter layer 620 may be appropriately (suitably) adjusted within the above range in consideration of the light transmittance of the color filter layer 620.

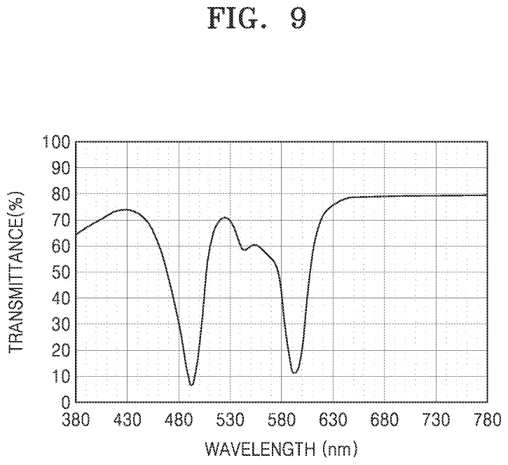

The reflection control layer 630 may be arranged on the color filter layer 620. The reflection control layer 630 may optionally absorb light of a wavelength in some ranges of the light reflected inside the display apparatus 1 or the light incident from the outside of the display apparatus 1. In the following description, the reflection control layer 630 is described in more detail with reference to FIG. 9.

FIG. 9 is a graph showing the light transmittance of the reflection control layer 630, according to an embodiment.

Referring to FIGS. 5 and 9 together, in FIG. 9, the reflection control layer 630 appears to absorb light of a first wavelength range of 480 nm to 500 nm and light of a second wavelength range of 585 nm to 605 nm. In this case, the light transmittance spectrum of the reflection control layer 630 may have a light transmittance of 40% or less in the first wavelength range and the second wavelength range. For example, the reflection control layer 630 may absorb light of a wavelength outside of the red, green, and blue light wavelength ranges of the first to third organic light-emitting diodes OLED1, OLED2, and OLED3. As such, as the reflection control layer 630 absorbs light of a wavelength that does not belong to the red, green, and blue light wavelength ranges of the first to third organic light-emitting diodes OLED1, OLED2, and OLED3, a decrease in the luminance of the display apparatus 1 may be prevented or reduced and simultaneously (concurrently) deterioration of the light-emitting efficiency of the display apparatus 1 may be prevented or reduced, thereby improving (increasing) visibility.

In another embodiment, unlike the graph of FIG. 9, the reflection control layer 630 may necessarily absorb light of the second wavelength range of 585 nm to 605 nm, and may optionally absorb light of the first wavelength range of 480 nm to 500 nm. For example, the reflection control layer 630 may not absorb light of the first wavelength range, and in some cases, to adjust the final luminous reflectance, may at least partially absorb the first wavelength range. In some embodiments, the reflection control layer 630 may optionally absorb light of a different wavelength range, for example, 410 nm to 440 nm.

In an embodiment, the reflection control layer 630 may be an organic material layer including dye, pigment, or a combination thereof. The reflection control layer 630 may include tetra aza porphyrin (TAP)-based compounds, porphyrin-based compounds, metal porphyrin-based compounds, oxazine-based compounds, squarylium-based compounds, triarylmethane-based compounds, polymethine-based compounds, anthraquinone-based compounds, phthalocyanine-based compounds, azo-based compounds, perylene-based compounds, xanthene-based compounds, diimmonium-based compounds, dipyrromethene-based compounds, cyanine-based compounds, and/or combinations thereof.

For example, the reflection control layer 630 may include a compound expressed by any one of Chemical Formulae 1 to 4. Chemical Formulae 1 to 4 may have a chromophore structure corresponding to compounds described above. Chemical Formulae 1 to 4 are examples, but the disclosure is not limited to these examples.

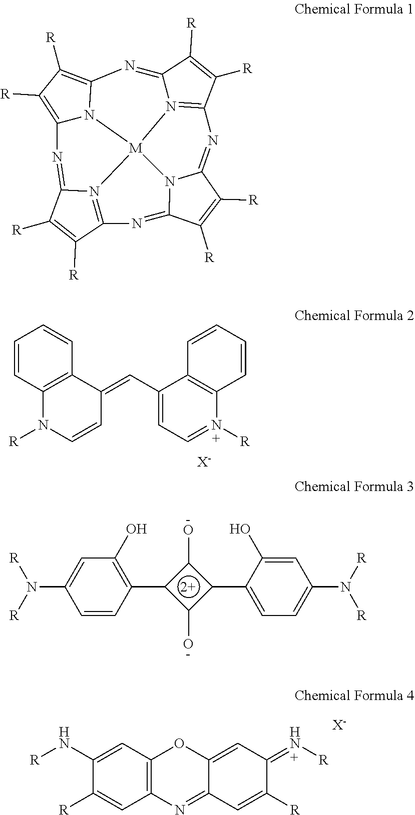

In Chemical Formulae 1 to 4,

M denotes a metal,

X⁻ denotes a monovalent negative ion,

R groups are the same or different from each other, and may each be a C₁-C₆₀ alkyl group, a C₂-C₆₀ alkenyl group, a C₂-C₆₀ alkynyl group, or a C₁-C₆₀ alkoxy group, which is unsubstituted or substituted with hydrogen, deuterium (-D), —F, —Cl, —Br, —I, a hydroxyl group, a cyano group, or a nitro group; deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof; or

a C₃-C₆₀ carbocyclic group, a C₁-C₆₀ heterocyclic group, a C₆-C₆₀ aryloxy group, or a C₆-C₆₀ arylthio group; or —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), which is unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof.

The Q₁ to Q₃, Q₁₁ to Q₁₃, Q₂₁ to Q₂₃, and Q₃₁ to Q₃₃ groups may each independently be hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; or a C₁-C₆₀ alkoxy group; or a C₃-C₆₀ carbocyclic group or a C₁-C₆₀ heterocyclic group, which is unsubstituted or substituted with deuterium, —F, a cyano group, a C₁-C₆₀ alkyl group, a C₁-C₆₀ alkoxy group, a phenyl group, a non-phenyl group, or any combination thereof.

In an embodiment, the X⁻ group may be a halide ion, a carboxylate ion, a nitrate ion, a sulfonate ion, or a bisulfate ion.

For example, the X⁻ group may be F⁻, Cl⁻, Br⁻, I⁻, CH₃COO⁻, NO₃_{^{−}}, HSO₄_{^{−}}, a propionate ion, a benzene sulfonate ion, and/or the like.

In an embodiment, reflectivity measured in a specular component included (SCI) mode on the surface of the reflection control layer 630 may be 10% or less. For example, as the reflection control layer 630 absorbs the reflection of external light of the display apparatus 1, visibility may be improved (increased).

In the display apparatus 1 according to an embodiment, in order to reduce the reflection of external light, a polarization film is not used, and the low reflection layer 300 and the reflection control layer 630 are introduced.

As a comparative example, when a polarization film (polarizer) is used to reduce the reflection of external light, the transmittance of light emitted from the first to third organic light-emitting diodes may be significantly reduced by the polarization film. When a red color filter, a green color filter, and a blue color filter corresponding to the color or each pixel is used to reduce the reflection of external light, a reflected color band may be generated according to reflectivity of light that differs for each pixel, and due to a large number of processes, process costs may be increased.

As the display apparatus 1 according to the embodiment discussed above includes the low reflection layer 300 and the reflection control layer 630 that are generally applied to each pixel, a light transmittance may be increased and simultaneously (concurrently) the reflection of external light may be reduced. Furthermore, by providing only the color filter layer 620 of a red color, light efficiency may be maximized (increased) and simultaneously (concurrently) the process may be simplified.

The reflection control layer 630 may be arranged across the entire surface of the display area DA to cover the color filter layer 620 and the light-shielding layer 610. As described above, unlike when the color filter layer 620 is arranged corresponding to only the first organic light-emitting diode OLED1, the reflection control layer 630 may be arranged across the first to third organic light-emitting diodes OLED1, OLED2, and OLED3. The reflection control layer 630 may be arranged on the color filter layer 620 above the first organic light-emitting diode OLED1, and the reflection control layer 630 may be arranged to cover the opening 610OP of the light-shielding layer 610 above the second organic light-emitting diode OLED2 and the third organic light-emitting diode OLED3. Accordingly, light L1 emitted from the first organic light-emitting diode OLED1 may pass through the color filter layer 620 and the reflection control layer 630, and light L2 and L3 respectively emitted from the second organic light-emitting diode OLED2 and the third organic light-emitting diode OLED3 may pass through the reflection control layer 630.

In an embodiment, the reflection control layer 630 may have a light transmittance of about 64% to 72%. The light transmittance of the reflection control layer 630 may be suitably adjusted depending on the content of pigment and/or dye included in the reflection control layer 630.

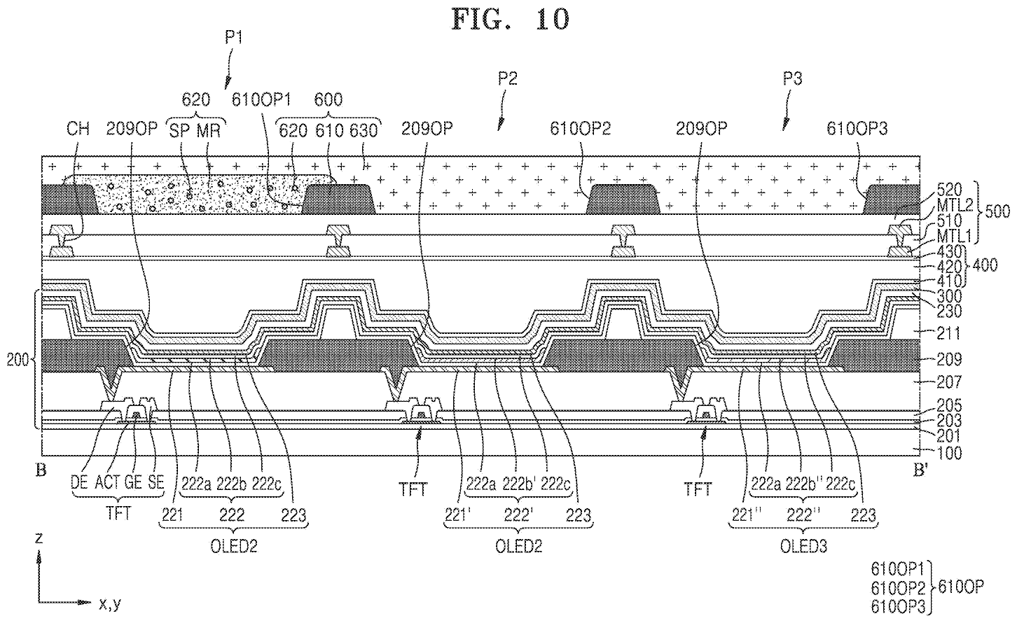

FIGS. 10 and 11 are schematic cross-sectional views of part of a display apparatus according to embodiments.

Referring to FIG. 10, the structure of the color filter layer 620 differs from the above-described embodiments. In the following description, the differences of the color filter layer 620 are described, and a redundant description thereof is not repeated here.

In an embodiment, the color filter layer 620 may include a scattering agent (SP). The color filter layer 620 may include a matrix MR formed of polymer photosensitive resin, and the scattering agent SP may be scattered in the matrix MR of the color filter layer 620. The matrix MR may further include pigment and/or dye other than a polymer photosensitive resin.

The scattering agent SP may include at least one of TiO₂, ZnO, Al₂O₃, SiO₂, hollow silica, and/or polystyrene particles. The scattering agent SP may include any one of TiO₂, ZnO, Al₂O₃, SiO₂, hollow silica, and polystyrene particles, or may be a mixture of materials of two or more substances selected from among TiO₂, ZnO, Al₂O₃, SiO₂, hollow silica, and polystyrene particles formed of polystyrene resin. For example, the color filter layer 620 may include TiO₂ as the scattering agent SP.

In an embodiment, the scattering agent SP may be a spherical (substantially spherical) particle. The disclosure is not limited thereto, and the scattering agent SP may be oval spherical (substantially oval spherical) or amorphous (substantially amorphous).

The average diameter of the scattering agent SP may be 500 nm or less. For example, the scattering agent SP may have an average diameter of 50 nm or more and 500 nm or less. The average diameter of the scattering agent SP may be, for example, a value obtained by arithmetically averaging the diameters in the cross-sections of a plurality of scattering agents SP. When the average diameter of the scattering agent SP is less than 50 nm, to show a scattering effect in the color filter layer 620, the amount of the scattering agent SP may be increased, and in this case, the light transmittance in the color filter layer 620 may be lowered. Furthermore, when the average diameter of the scattering agent SP is decreased to less than 50 nm, as a change in the relative luminance value according to a viewing angle in the color filter layer 620 increases, a color difference according to the viewing angle is reduced so that an effect of improving (increasing) display quality may not be obtained. Furthermore, when the average diameter of the scattering agent SP exceeds 500 nm, due to a relatively large size of a particle, the film properties may be determined during the formation of the color filter layer 620. Furthermore, when the average diameter of the scattering agent SP exceeds 500 nm, in a manufacturing process, resin for forming the color filter layer 620 may be difficult to eject from a nozzle.

As described above, the color filter layer 620 according to an embodiment may include the scattering agent SP to minimize (reduce) the reduction of front side luminance and also reduce a luminance difference according to the viewing angle. Accordingly, a display quality difference according to the viewing angle may be improved.

Referring to FIG. 11, a stack structure corresponding to one pixel of an embodiment is illustrated. FIG. 11 shows a difference from the above-described embodiments in connection with the thickness of the color filter layer 620. In the following description, the differences in the color filter layer 620 are described, and a redundant description thereof is not repeated here.

In an embodiment, the color filter layer 620 may have a second thickness t2. The second thickness t1 of the color filter layer 620 in FIG. 5 may be about 0.9 μm to 3.0 μm. In more detail, the second thickness t2 of the color filter layer 620 may be about 0.9 μm to 1.5 μm. This is a decrease by about 50%-70%, compared with the first thickness t1 of the color filter layer 620 of FIG. 5. In this case, the second thickness t2 of the color filter layer 620 may be less than the thickness of the body part of the light-shielding layer 610.

As such, by adjusting the thickness of the color filter layer 620, the light transmittance of a short wavelength range such as blue light may be slightly increased, for example, by about 15%. However, such is not the same degree in affecting the characteristics of the color filter layer 620, and instead, light efficiency in the same reflectivity may be increased through the light corresponding to the increased light transmittance. This may be confirmed through Embodiment 2 in Table 1 described below.

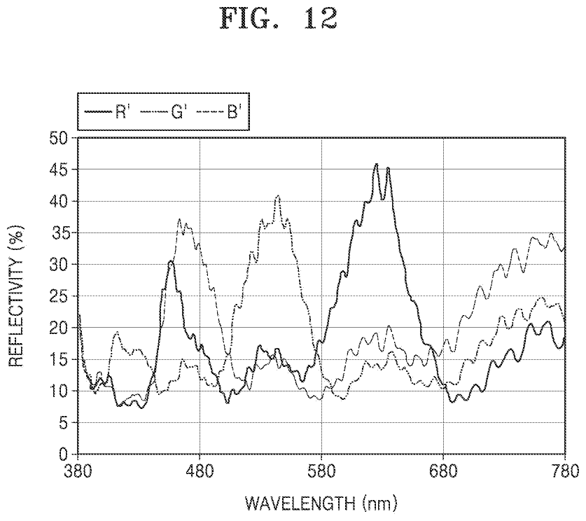

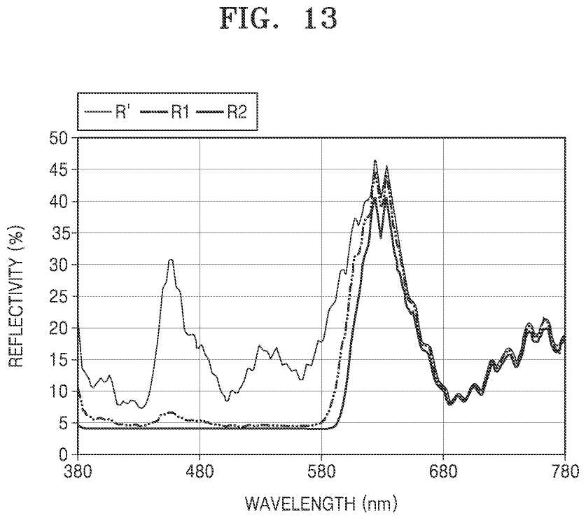

FIG. 12 is a graph showing the reflection spectrums of each of a first pixel, a second pixel, and a third pixel, according to Comparative Example 1. FIG. 13 is a graph showing the reflection spectrum of the first pixel, according to an embodiment.

Referring to the graph of FIG. 12, the reflection spectrum of Comparative Example 1 to which the color filter layer and the reflection control layer are not applied is measured. In FIG. 12, each of a red pixel R′ for emitting red light, a green pixel G′ for emitting green light, and a blue pixel B′ for emitting blue light is measured.

Comparative Example 1 includes the low reflection layer 300 described above in FIG. 5. In FIG. 12, it may be confirmed that the green pixel G′ and the blue pixel B′ have low reflectivity in an area other than the green wavelength range and the blue wavelength range, whereas the red pixel R′ has high reflectivity with respect to the red light in a wavelength range of about 400 nm to 550 nm, in particular, the blue light wavelength range. The light emitted from the red pixel R′ having high reflectivity in the blue light wavelength range may serve as a factor to lower the light efficiency in a display area.

Accordingly, referring to the graph of FIG. 13, the reflection spectrum of each of the red pixel R′ according to Comparative Example 1 of FIG. 12, a red pixel R1 according to Embodiment 1, and a red pixel R2 according to Embodiment 2 is measured on the basis of the first organic light-emitting diode for emitting red light.

For the red pixel R′ according to Comparative Example 1, as described above with reference to FIG. 12, it may be confirmed that the reflectivity of red light is high in a wavelength range of about 400 nm to 550 nm, for example, the blue light wavelength range.

In Embodiment 1 and Embodiment 2, the low reflection layer 300, the color filter layer 620, and the reflection control layer 630 are provided. In Embodiment 1, the thickness of the color filter layer 620 is about 2.7 μm to 3.0 μm, and in Embodiment 2, the thickness of the color filter layer 620 is about 0.9 μm to 1.5 μm. As in Embodiment 1 and Embodiment 2, when the color filter layer 620 and the reflection control layer 630 are provided above the low reflection layer 300, it may be confirmed that the reflectivity of both of the red pixel R1 of Embodiment 1 and the red pixel R2 of Embodiment 2 are decreased by about 5% in a wavelength of about 580 nm or less. As such, by providing the color filter layer 620 and the reflection control layer 630 above the first organic light-emitting diode OLED1 for emitting red light, the reflectivity of red light in a wavelength range of about 580 nm or less, in more detail, 400 nm to 550 nm, is reduced so that the light efficiency of the display apparatus 1 may be improved.

TABLE 1

| | Comparative | | |
|---|---|---|---|
| | Example 2 | Embodiment 1 | Embodiment 2 |
| Reflectivity | 5.30% | 5.30% | 5.30% |
| Efficiency Ratio | 125.6% | 135.5% | 137.5% |

Referring to Table 1, shown are the efficiency ratios of Comparative Example 2, Embodiment 1, and Embodiment 2 at the same reflectivity. Embodiment 1 and

Embodiment 2 are the same as Embodiment 1 and Embodiment 2 that are described above in FIG. 13. Comparative Example 2 is a structure that includes the low reflection layer 300 and the reflection control layer 630, but to which the color filter layer 620 is not applied.

It may be seen that, with respect to the reflectivity of 5.30%, for Comparative

Example 2, the efficiency is increased by 125.6%, compared with the structure employing the polarization film (polarizer). In contrast, it may be seen that, for Embodiment 1 and Embodiment 2 to which the color filter layer 620 is applied corresponding to the first red pixel, the efficiency to the structure employing the polarization film (polarizer) is improved by 135.5% and 137.5%, respectively. This confirms that the efficiency of about 10% is increases compared with Comparative

### Example 2.

TABLE 2

| (Based on the | Comparative | | |
|---|---|---|---|
| same reflectivity) | Example 2 | Embodiment 1 | Embodiment 2 |
| Thickness of Color | — | 0.9 μm-1.5 μm | 2.7 μm-3.0 μm |
| Filter Layer | | | |
| Light Transmittance | — | @460 nm | @460 nm |
| of Color Filter | | 0-2.0% | 12-30% |
| Layer for Each | | @550 nm | @550 nm |
| Wavelength | | 0-1.0% | 4-16% |
| Range (Based on | | @650 nm | @650 nm |
| Air 100%) | | 65-70% | 80-90% |
| Light Transmittance | 60%-64% | 64%-72% | |
| of Reflection | | | |
| Control Layer | | | |

| | | |
|---|---|---|
| Light Transmittance | @460 nm | @460 nm |
| of Reflection | 70-76% | 76-90% |
| Control Layer | @550 nm | @550 nm |
| for Each | 60-65% | 66-72% |
| Wavelength | @650 nm | @650 nm |
| Range | 73-78% | 79-86% |

Referring to Table 2, the light transmittance (for each wavelength range) is shown for Comparative Example 2, Embodiment 1, and Embodiment 2 at the same reflectivity.

The first to third organic light-emitting diodes OLED1, OLED2, and OLED3 of the display apparatus 1 according to an embodiment may respectively emit red, green, and blue light. In this state, the maximum peak wavelength of the blue light may be about 460 nm, the maximum peak wavelength of the green light may be about 550 nm, and the maximum peak wavelength of the red light may be about 650 nm.

The reflection control layer 630 may have a light transmittance of about 64% to 72%. In more detail, the reflection control layer 630 may have a light transmittance of about 76% to 90% at the maximum peak wavelength of the blue light, a light transmittance of about 66% to 72% at the maximum peak wavelength of the green light, and a light transmittance of about 79% to 86% at the maximum peak wavelength of the red light.

Comparative Example 2 is assumed to have a structure in which the color filter layer 620 is not provided, for example, not a color filter layer, but a reflection control layer only is arranged above the first organic light-emitting diode for emitting light of a red wavelength. In this case, as the color filter layer does not absorb light of a wavelength other than the red wavelength, the reflection control layer may necessarily include pigment and/or dye more than the reflection control layer 630 according to an embodiment. For Comparative Example 2, the reflection control layer may have a light transmittance of about 60% to 64%. The reflection control layer 630 according to an embodiment has a light transmittance of about 64% to 72%, and thus it may be confirmed that the light transmittance is improved compared with Comparative Example 2. The light efficiency of the display apparatus may be improved through such improvement of light transmittance.

According to the above-described embodiment, display apparatuses having improved visibility may be implemented by reducing the reflection of external light. The scope of the disclosure is not limited by the above effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various suitable changes in form and details may be made therein without departing from the spirit and scope as defined by the following claims, and equivalents thereof.

What is claimed is:

1. A display apparatus comprising:
a substrate;
a first light-emitting device, a second light-emitting device, and a third light-emitting device, which are arranged on the substrate and respectively form emission areas by emitting light of wavelengths different from one another;
a low-reflection layer arranged on the first light-emitting device, the second light-emitting device, and the third light-emitting device, wherein the low-reflection layer comprises an inorganic material;
a light-shielding layer arranged above the low-reflection layer, corresponding to a non-emission area between the emission areas, wherein the light-shielding layer comprises openings corresponding to the emissions areas;
a color filter layer arranged in the openings of the light-shielding layer, corresponding to only the first light-emitting device among the first light-emitting device, the second light-emitting device, and the third light-emitting device; and
a reflection control layer arranged on the light-shielding layer and the color filter layer.

2. The display apparatus of claim 1, wherein the first light-emitting device emits light of a red wavelength.

3. The display apparatus of claim 1, wherein the color filter layer transmits light in a red wavelength range.

4. The display apparatus of claim 1, wherein the openings of the light-shielding layer comprise a first opening corresponding to the first light-emitting device, a second opening corresponding to the second light-emitting device, and a third opening corresponding to the third light-emitting device, and
the color filter layer is arranged only in the first opening.

5. The display apparatus of claim 4, wherein the reflection control layer is arranged to fill the second opening and the third opening.

6. The display apparatus of claim 1, wherein a thickness of the color filter layer is 0.9 μm to 3.0 μm.

7. The display apparatus of claim 1, wherein a light transmittance of the color filter layer is 70% or more in a red wavelength range, and 50% or less in a green wavelength range and a blue wavelength range.

8. The display apparatus of claim 1, wherein the color filter layer comprises a scattering agent.

9. The display apparatus of claim 8, wherein the scattering agent comprises at least one of TiO₂, ZnO, Al₂O₃, SiO₂, hollow silica, or polystyrene particles.

10. The display apparatus of claim 8, wherein the scattering agent has an average diameter of 50 nm or more and 500 nm or less.

11. The display apparatus of claim 1, wherein the reflection control layer comprises dye, pigment, or a combination thereof.

12. The display apparatus of claim 11, wherein a light transmittance of the reflection control layer is about 64% to about 72%.

13. The display apparatus of claim 1, wherein the low-reflection layer comprises at least one of a metal and a metal oxide.

14. The display apparatus of claim 13, wherein the low-reflection layer comprises ytterbium (Yb), bismuth (Bi), cobalt (Co), molybdenum (Mo), titanium (Ti), zirconium (Zr), aluminum (Al), chromium (Cr), niobium (Nb), platinum (Pt), tungsten (W), indium (In), tin (Sn), iron (Fe), nickel (Ni), tantalum (Ta), manganese (Mn), zinc (Zn), germanium (Ge), silver (Ag), magnesium (Mg), gold (Au), copper (Cu), calcium (Ca), or a combination thereof.

15. The display apparatus of claim 13, wherein the low-reflection layer has a refractive index (n) of 1 or more.

16. The display apparatus of claim 1, wherein the reflection control layer absorbs a second wavelength range of a visible light range, and optionally absorbs a first wavelength range of the visible light range.

17. The display apparatus of claim 16, wherein the first wavelength range is about 480 nm to about 500 nm, and the second wavelength range is about 585 nm to about 605 nm.

18. The display apparatus of claim 1, wherein the first light-emitting device comprises a first pixel electrode, the second light-emitting device comprises a second pixel electrode, and the third light-emitting device comprises a third pixel electrode,
the display apparatus further comprises a pixel-defining layer covering edges of the first pixel electrode, the second pixel electrode, and the third pixel electrode, and has an opening portion that exposes a center portion of each of the first pixel electrode, the second pixel electrode, and the third pixel electrode,
wherein the pixel-defining layer comprises a light-blocking material.

19. The display apparatus of claim 1, further comprising a capping layer arranged on the first light-emitting device, the second light-emitting device, and the third light-emitting device,
wherein the capping layer comprises an organic material, and
wherein the low-reflection layer is arranged directly on the capping layer.

20. The display apparatus of claim 1, further comprising:
a thin-film encapsulation layer arranged on the low-reflection layer; and
a touch-sensing layer arranged on the thin-film encapsulation layer,
wherein the light-shielding layer is arranged on the touch-sensing layer.
